(19) United States
(12) Patent Application Publication
(10) Pub. No.: US 2025/0271254 A1
(43) Pub. Date: Aug. 28, 2025

(54) SEMICONDUCTOR MEASUREMENT DEVICE AND OPERATING METHOD THEREOF

(71) Applicant: Samsung Electronics Co., Ltd., Suwon-si (KR)

(72) Inventors: Jaehwang JUNG, Suwon-si (KR); Jinwoo AHN, Suwon-si (KR)

(73) Assignee: Samsung Electronics Co., Ltd., Suwon-si (KR)

(21) Appl. No.: 18/884,420

(22) Filed: Sep. 13, 2024

(30) Foreign Application Priority Data
Feb. 27, 2024 (KR) 10-2024-0028081

(51) Int. Cl. G01B 9/021; G01B 11/06; G01N 21/45

(52) U.S. Cl. CPC G01B 9/021; G01B 11/0675; G01N 21/453

(57) ABSTRACT

An operating method of a semiconductor measurement device according to the present disclosure may include, irradiating monochromatic light to a sample, separating light reflected from the sample, generating an off-axis interference pattern from the separated light, and measuring reflectance information of the reflected light using a Kramers-Kronig relation from the off-axis interference pattern.

### CROSS-REFERENCE TO RELATED APPLICATION(S)

This application claims benefit of priority to Korean Patent Application No. 10-2024-0028081 filed on Feb. 27, 2024, in the Korean Intellectual Property Office, the disclosure of which is incorporated herein by reference in its entirety.

### BACKGROUND

The present disclosure relates to a semiconductor measurement device and an operating method thereof.

Generally, ellipsometry in semiconductor measurement devices is a non-destructive analysis technique used to measure parameters (such as thickness, refractive index, and surface condition) of semiconductor materials. This technique is widely employed for investigating properties such as thickness and refractive index of thin films, as well as surface characteristics at thin film interfaces. The operating principle of ellipsometry primarily relies on observing changes in the polarization state of light. The information obtained from these measurements is utilized to determine various physical properties associated with semiconductor thin films, including thickness, refractive index, and optical constants.

### SUMMARY

An aspect of the present disclosure is to provide a semiconductor measurement device configured to clearly restore reflectance information and an operating method thereof.

According to an aspect of the present disclosure, an operating method of a semiconductor measurement device including an optical system; the method may include: aligning the optical system and a sample to be measured; adjusting an angle of an analyzer included in the optical system to extinguish, with an interference generator, a first electromagnetic field from a light reflected from the sample, the light including the first electromagnetic field and a second electromagnetic field; measuring an intensity of the second electromagnetic field; generating a hologram of the sample by rotating the analyzer to a first rotation angle; and measuring an interference pattern by measuring an intensity of the hologram.

According to another aspect of the present disclosure, an operating method of a semiconductor measurement device may include: irradiating a light to a sample; measuring an intensity of an electromagnetic field and an intensity of a hologram corresponding to an interference pattern from light reflected from the sample; and restoring reflectance information about the sample based on a Kramers-Kronig relation using the measured intensity of the electromagnetic field and the measured intensity of the hologram.

According to another aspect of the present disclosure, an operating method of a semiconductor measurement device may include: irradiating monochromatic light to a sample; separating light reflected from the sample into at least two electromagnetic fields; generating an off-axis interference pattern from the separated light; and determining reflectance information of the reflected light from the off-axis interference pattern based on a Kramers-Kronig relation of the separated light.

According to another aspect of the present disclosure, a semiconductor measurement device may include: a stage for moving a wafer; a light source generating monochromatic light; an optical illumination system configured to irradiate the monochromatic light to a sample on the wafer; an optical vision system configured to align the wafer; a first detector configured to detect an image of reflected light reflected from the sample at an imaging plane; an interference generator configured to generate off-axis self-interference for the reflected light; a second detector configured to detect a holographic image corresponding to the off-axis self-interference in a pupil plane; and an off-axis analyzing device configured to restore reflectance information from the holographic image using a Kramers-Kronig relation.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a view illustrating a semiconductor measurement device according to at least one embodiment of the present disclosure;

FIG. 2 is a view illustrating a beam splitting device illustrated in FIG. 1;

FIG. 3 is a view illustrating an off-axis interference pattern according to at least one embodiment of the present disclosure;

FIG. 4 is a view illustrating a self-interference pupil polarization analysis method using off-axis interference in a conventional semiconductor measurement device;

FIG. 5 is a view illustrating separation and a band of the present disclosure;

FIG. 6 is a flowchart illustrating a measurement operation of a semiconductor measurement device according to at least one embodiment of the present disclosure;

FIG. 7A is a view illustrating measured I₂, and FIG. 7B is a view illustrating measured I_{H};

FIG. 8 is a flowchart illustrating a signal restoration operation of an off-axis analyzing device according to at least one embodiment of the present disclosure;

FIG. 9 is a view comparing restoration results according to a separation/band ratio according to a conventional FT restoration method and a KK restoration method of the present disclosure;

FIG. 10 is a view illustrating reconstruction accuracy of a semiconductor measurement device according to at least one embodiment of the present disclosure;

FIG. 11 is a view illustrating a signal restoration result of a semiconductor measurement device according to at least one embodiment of the present disclosure;

FIGS. 12A and 12B are views illustrating a maximum signal region ratio in a camera reference horizontal (or vertical) off-axis structure;

FIGS. 13A and 13B are views illustrating a maximum signal region ratio when a structure is diagonally off-axis relative to a camera; and

FIG. 14 is a view illustrating a computing device configured to process an off-axis interference analysis according to at least one embodiment of the present disclosure.

### DETAILED DESCRIPTION

Hereinafter, contents of the present disclosure may be described clearly and in detail so that a person skilled in the art may easily implement the present disclosure, using the accompanying drawings. It will be understood that although terms such as “first” and “second” may be used herein to describe various components, these components should not be limited by these terms. These terms are only used to distinguish one element from another. Additionally, when the terms “approximately” or “substantially” are used in this specification in connection with a numerical value and/or geometric terms, it is intended that the associated numerical value includes a manufacturing tolerance (e.g., ±10%) around the stated numerical value. Further, regardless of whether numerical values and/or geometric terms are modified as “approximately” or “substantially,” it will be understood that these values should be construed as including a manufacturing or operational tolerance (e.g., ±10%) around the stated numerical values and/or geometry.

In accordance with some embodiments of the present invention, a semiconductor measurement device and an operating method may perform semiconductor structure measurements based on interference signals. The semiconductor measurement device of the present invention may include a self-interference-based signal measurement device and may be configured to perform holographic signal reconstruction based on Kramers-Kronig (KK) relations. The semiconductor measurement device and the operating method of the present invention have values larger than the signal bandwidth without distortion in separation conditions. The semiconductor measurement device and the operating method of the present invention may relax separation angle conditions defined by off-axis angles. Here, off-axis angles refer to angles measured at different angles compared to a specific axis or direction in the semiconductor measurement device. Additionally, the semiconductor measurement device and the operating method of the present invention can significantly increase the signal bandwidth compared to Fourier transform-based restoration under the same and/or comparative separation conditions.

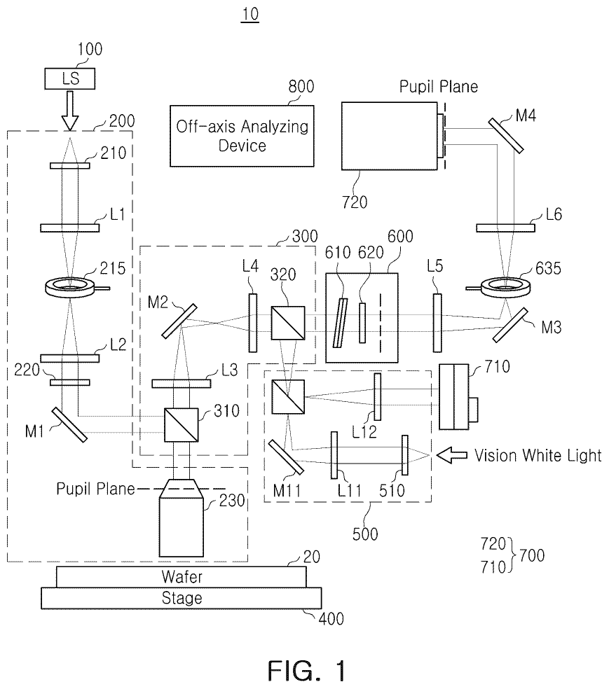

FIG. 1 is a view illustrating a semiconductor measurement device 10 according to at least one embodiment of the present disclosure. The semiconductor measurement device 10 illustrated in FIG. 1 may be implemented as a pupil elliptical polarization measurement device. Referring to FIG. 1, the semiconductor measurement device 10 may include a light source device 100 (LS), an optical illumination system 200, a beam splitter 300, a stage 400, an optical vision system 500, a self-interference generator 600 (SIG or interference generator), a detection device 700, and an off-axis analyzing device 800. The semiconductor measurement device 10 may further include processing circuitry (not illustrated) configured to control the operation of the semiconductor measurement device 10. For example, the processing circuitry may be configured to control the activation, timing, synchronization, operations, positioning etc. of the light source device 100 (LS), the optical illumination system 200, the beam splitter 300, the stage 400, the optical vision system 500, the interference generator 600, the detection device 700, the off-axis analyzing device 800, included in the semiconductor measurement device 10 and/or the components therein. The detection device 700 may include a first detection device 710 and a second detection device 720.

The light source device 100 may be configured to generate light of a preset wavelength and to input the light into the optical illumination system 200. For example, the light source device 100 may generate and output coherent light. The coherent light may refer to light that causes interference (such as constructive interference and/or destructive interference) due to a phase difference when two or more light portions overlap. For example, the light source device 100 may include a light source and a monochromator. The light source may generate and output broadband light. The monochromator may convert the broadband light into monochromatic light and output the light. The light source device 100 may operate by converting broadband light from the light source into monochromatic light of a wavelength selected by the monochromator and outputting the monochromatic light. Meanwhile, at least one embodiment, the light source device 100 may be implemented by including a plurality of point sources that output monochromatic light. In at least some embodiments, the light source device 100 may use the monochromatic light during measurement, but may be configured to change the wavelength as needed.

The optical illumination system 200 may be configured to irradiate light incident from the light source device 100 through an optical fiber to a sample 20 using a plurality of optical elements. For example, the optical illumination system 200 may include a collimator 210, an aperture 215, a polarizer 220 (first polarizer), and an objective lens 230.

The collimator 210 may be configured to transform the incident monochromatic light into parallel light. The aperture 215 may be configured to adjust a size of a beam spot irradiated to the sample. The polarizer 220 may be configured to polarize light from the collimator 210 and to output the light. For example, the polarization may be linear polarization. The linear polarization may refer to converting incident light into linearly polarized light by passing only a P-polarization component (or a horizontal component) or an S-polarization component (or a vertical component). According to at least one embodiment, the polarizer 220 may perform circular polarization or elliptical polarization.

The objective lens 230 may be configured to focus light from a first beam splitter 310 onto the sample 20 and allow the light to be incident thereto. An angle of incidence (0) of light focused by the objective lens 230 may be influenced by the numerical aperture (NA) of the objective lens 230. In other words, when a refractive index of air is 1, this may have a relationship NA=sin θ. Accordingly, as NA is closer to 1, the angle of incidence may be closer to 90°. Due to the focusing action of the objective lens 230, light components incident through different positions of the objective lens 230 may have different incident angles and azimuth angles.

In the semiconductor measurement device 10 of the present disclosure, a second detector 720 may be configured to detect an image in a pupil plane, that is, a pupil image, with respect to the sample 20. Each of the pixels of the pupil image corresponds to a different position on the objective lens 230, and accordingly, may include reflectance information for light components incident through different positions of the objective lens 230 and having different angles of incidence and azimuth. Based on the objective lens 230 and the pupil image, reflectance information for light components at various angles of incidence and azimuth may be obtained.

Meanwhile, the reflected light reflected from the sample 20 may be incident on the first beam splitter 310 through the objective lens 230. According to at least one embodiment, the first beam splitter 310 may be included in the optical illumination system 200. Additionally, according to at least one embodiment, the optical illumination system 200 may further include at least one optical element other than the optical elements described above.

The beam splitter 300 may include a first beam splitter 310 and a second beam splitter 320. The first beam splitter 310 may be configured to allow polarized light through a first polarizer 220 to be emitted toward the objective lens 230, and to allow light reflected from the sample 20 and incident through the objective lens 230 to be emitted toward the second beam splitter 320. The second beam splitter 320 may be configured to emit a portion of the light from the first beam splitter 310 toward a first detector 710, and to emit the remaining portion toward the interference generator 600.

The stage 400 may be configured to support and secure the sample 20. For example, the sample 20 may be disposed on an upper surface of the stage 400, and the stage 400 may support and secure a lower surface of the sample 20. The stage 400 may be a three-dimensional moving stage that may move in three dimensions. As the stage 400 moves, the sample 20 may also move together. For example, through the movement of the stage 400, focusing on a Z-axis or a movement on an X-Y plane may be performed on the sample 20. Here, the Z-axis corresponds to a normal line, perpendicular to the upper surface of the stage 400 or the sample 20, and the X-Y plane may correspond to the upper surface of the stage 400 or the sample 20, or a plane, perpendicular to the Z-axis. In at least some embodiments, the movement of the stage 400 may be enabled by, e.g., motors, gears, actuators, etc. connected to the stage 400, and the operation thereof may be controlled, e.g., by processing circuitry.

Meanwhile, the sample 20 may be, for example, a mask or a wafer including a pattern. Additionally, the sample 20 may be a semiconductor device including multiple pattern layers or overlay marks. The semiconductor measurement device 10 of this example embodiment may measure and analyze various characteristics of the sample 20. For example, the light polarized through the polarizer 220 may be reflected from the sample 20, and a polarization state may change depending on a state of the sample 20.

The semiconductor measurement device 10 may be configured to measure/analyze various characteristics of the sample 20 (overlay errors, a pattern size, a pattern thickness, a pattern uniformity, and/or the like) by detecting the light reflected from the sample 20 and analyzing a polarization state. Additionally, the semiconductor measurement device 10 may detect defects (such as pattern defects and/or foreign substances) in the sample 20.

Meanwhile, the measurement and analysis of the sample 20 may be accomplished by comparing the reflectance information obtained through the second detector 720 and the holographic restoration process with reference information stored in the database. Additionally, according to example embodiments, the measurement and analysis of the sample 20 may be accomplished through learning based on reflectance information for a plurality of samples 20 obtained through the semiconductor measurement device 10.

The optical vision system (500; 510, L11, L12, M11) is an optical system for wafer alignment. The optical vision system 500 may operate using various optical components and an image sensor. The optical vision system 500 may first illuminate a surface of the wafer, may collect illuminated images with an image sensor, may process the collected images using computer vision algorithms and may identify a location, an orientation, and features of the wafer. The optical vision system 500 may further include processing circuitry configured to perform the computer vision algorithms and identifications.

Meanwhile, in FIG. 1, a plurality of relay optical systems are included. For example, first relay optical systems L1, L2 and M1, second relay optical systems L3, L4 and M2, and third relay optical systems L5, L6, M3 and M4 are illustrated. In at least one embodiment, the relay optical systems L3, L4 and M2 may transmit light from the objective lens 230 to the first detector 710 and the interference generator 600. For example, the relay optical system may include a relay lens and an imaging lens. The relay lens may be comprised of a pair of two lenses, and may transfer light from the first beam splitter 310 to the second beam splitter 320. The imaging lens may form an image of the light from the second beam splitter 320 to the first detector 710. The imaging lens may be, for example, a tube lens. According to at least one embodiment, the second beam splitter 320 may be included in the relay optical system. Additionally, according to at least one embodiment, the relay optical system may further include at least one optical element (e.g., a mirror) other than the relay lens and the imaging lens.

The interference generator 600 may be configured to generate interference light through self-interference with respect to light incident through the second beam splitter 320. Here, the light incident onto the interference generator 600 through the second beam splitter 320 may correspond to reflected light in which light polarized by the polarizer 220 is reflected from the sample 20 and transmitted through optical elements between the sample 20 and the interference generator 600. Meanwhile, as described above, the light polarized by the first polarizer 220 may be reflected from the sample 20 to change the polarization state, and accordingly, various characteristics of the sample 20 may be measured by detecting the reflected light and analyzing the polarization state.

The interference generator 600 may include a polarizing prism 610 and a second polarizer 620 to generate interference light through self-interference. The polarizing prism 610 may be configured to separate incident light into light of different polarization states. For example, the polarizing prism 610 may separate incident light into vertically polarized light and horizontally polarized light and may emit the light. In at least one embodiment, the polarizing prism 610 may be implemented as a Nomarski prism, a Wollaston prism, a Rochon prism, and/or the like. The second polarizer 620 may allow the two polarized light portions separated through the polarizing prism 610 to have a common polarization component. For example, the second polarizer 620 may be a polarizer that passes only intermediate polarization between vertical polarization and horizontal polarization, for example, a 45° polarization component. Accordingly, the common polarization component corresponding to the 45° polarization component of the vertically polarized light and the horizontally polarized light from the polarizing prism 610 may pass through the second polarizer 620. Additionally, the two light portions passing through the second polarizer 620 may perform self-interference in the pupil plane to generate interference light.

The detection device 700 may include the first detector 710 and the second detector 720. The first detector 710 may detect an image of reflected light in which an image is formed on the imaging plane IP through an imaging lens. The first detector 710 may be a 2D array detector and may be, for example, a Charge-Coupled Device (CCD) camera. The first detector 710 is not limited to the CCD camera. The first detector 710 may be disposed on the imaging plane and may be used to confirm a measurement position for the sample 20 and an optimal focus position in an optical axis direction.

The second detector 720 may be configured to detect an image for the interference light generated through self-interference by the interference generator 600, that is, a hologram image, in the pupil plane. In general, when light is detected on the pupil plane, an intensity of the light may be measured more accurately. Accordingly, the second detector 720 may measure an intensity of the holographic image more accurately. The second detector 720 may be implemented with, for example, a CCD camera or a Photo-Multiplier Tube (PMT). However, the second detector 720 is not limited to the devices described above. Meanwhile, the pupil plane in an upper portion of the objective lens 230 is known as a back focal plane. The pupil plane in a lower portion of the second detector 720 may be an exit pupil plane.

For reference, generally, holographic images may be generated using a holographic principle. The holographic principle is as follows. The light from the light source is divided into two, and one light is reflected from a reference mirror and is illuminated on a screen, and the other light is reflected by an object to be measured and is illuminated on the screen. In this case, the light reflected from the reference mirror is known as a reference beam, and the light reflected from the object is known as an object beam. Since object light is the light reflected from a surface of an object, a phase thereof varies depending on each position on the surface of the object. Accordingly, the reference light and the object light may cause interference and an interference pattern may be formed on the screen. An image of the interference pattern is known as a holographic image. A general image includes only light intensity information, but the holographic image may include light intensity and phase information.

The off-axis analyzing device 800 may be implemented to measure/recover self-interference of light reflected from the sample 20. For example, the off-axis analyzing device 800 may be configured to calculate complex information corresponding to reflectance information using a Kramers-Kronig relation. Separation is a value obtained by dividing a sin function value of an off-axis angle by a wavelength, and a band is proportional to a radius of the illumination spot on the wafer and is inversely proportional to a focal length of the objective lens. Here, when the separation is greater than the band, the off-axis analyzing device 800 may restore reflectance information.

The semiconductor measurement device 10 according to at least one embodiment of the present disclosure may detect a holographic image through self-interference using the interference generator 600, instead of an interference method of reference light and object light using a reference mirror. Additionally, the semiconductor measurement device 10 may more accurately measure the intensity of the holographic image on the pupil plane through the second detector 720, by detecting the holographic image. Accordingly, through a subsequent holographic restoration process, reflectance information corresponding to polarization characteristics of the interference light may be calculated more accurately; and, therefore, images produced based on the results of the holographic restoration process are also produced more accurately. The semiconductor measurement device 10 may acquire reflectance information corresponding to all azimuths and angles of incidence through one shot, using the objective lens 230 and a pupil image corresponding thereto. Accordingly, the sample 20 may be measured significantly quickly and accurately without the need to adjust the incident angle and azimuth angle of the light incident to the sample 20. Additionally, a cross-correlation problem, in which similar spectra are obtained for different parameter changes in a specific structure, may be solved. In general, reflectance information is information about the polarization characteristics of light, and may usually be expressed as psi (v) and delta (4). Here, y refers to interference light, that is, a ratio of the intensity of two interference light portions, and A refers to a phase difference between two interference light portions. The reflectance information may also be expressed as alpha (a) and beta (B), which are known as elliptic constants. Between ψ and Δ and α and β, tan ψ={(1+α)/(1−α)}½ and Cos A=B/(1−α2)½ are satisfied. Here, ψ and Δ may be used in a holographic restoration process.

The semiconductor measurement device 10 according to at least one embodiment of the present disclosure may include a wafer transfer device, an optical illumination system, a measurement device configured to measure light through an objective lens, a beam separation unit configured to generate off-axis self-interference by separating the light reflected from the sample into two perpendicular polarizations, and an imaging system for wafer alignment. Additionally, the semiconductor measurement device 10 may be provided with a personal computer (PC), a control device, a storage device, a computing device, and the like, as needed. The semiconductor measurement device 10 according to at least one embodiment of the present disclosure may be used as an optical critical dimension (OCD) facility.

A conventional semiconductor measurement device acquires signals in the form of off-axis self-interference, analyzes and restores an interference pattern, and measures a structure thereof. Here, off-axis analysis generally separates AC and DC signals based on Fourier transform, and obtains only the AC signal and restores the signal. For an off-axis optical structure, an angle between the two interference beams is decisive. When the angle is significantly small, overlap between a desired AC signal and an unwanted DC signal may occur, and when the angle is significantly large, the clarity of the interference pattern may decrease, so that when configuring an optical system, various conditions are complexly considered. For this reason, it may not be possible to freely perform a design in a direction of increasing the off-axis angle, and limitations in signal separation may be caused. Because the conventional semiconductor measurement device uses an off-axis of self-interference pupil ellipses, this is not free from signal overlap. Accordingly, the conventional semiconductor measurement device generates noise when separating/recovering signals using a Fourier transform-based method.

On the other hand, the semiconductor measurement device 10 according to at least one embodiment of the present disclosure restores the holographic signal based on the Kramers-Kronig relation, a separation angle condition may be alleviated and a signal band may be increased during the same separation.

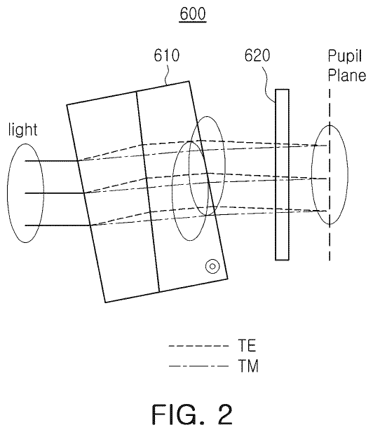

FIG. 2 is a view illustrating an interference generator 600 illustrated in FIG. 1. Referring to FIG. 2, the interference generator 600 may also be referred to as a beam splitting device 600, and may include a first polarizer (e.g., a polarizing prism) 610 and a second polarizer (e.g., a polarizer) 620. Here, two interfering light portions TE and TM are referred to as E1 and E2, respectively. The off-axis interference between two perpendicular polarizations on the pupil plane (or a back-focal plane) may be measured/analyzed. The polarizing prism 610 may be implemented as a Nomarski prism. In at least one embodiment, the polarizing prism 610 may determine an off-axis angle. When designing a polarizing prism, a size of a module, the physical properties of the prism, and information on a wavelength may be taken into consideration in a complex manner. The Nomarski prism is a beam separation unit for off-axis self-interference, and be implemented with birefringence crystals, gratings, a polarizer, and the like.

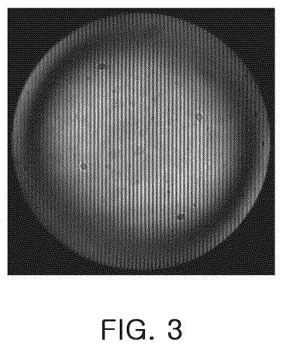

FIG. 3 is a view illustrating an off-axis interference pattern according to at least one embodiment of the present disclosure. As illustrated in FIG. 3, the off-axis interference pattern is a holographic image with an interference pattern. In general, the holographic image may be generated using the holographic principle. The holographic principle may be the same (and/or a similar) holographic principle as described with reference to FIG. 1. For example, the light from the light source may be divided into two, and one light reflected from the reference mirror and illuminated on the screen, and the other light reflected by the object to be measured and illuminated on the screen. In this case, the light reflected from the reference mirror is referred to as a reference beam, and the light reflected from the object is referred to as an object beam. Since the object light is light reflected from a surface of an object, a phase thereof varies depending on each position on the surface of the object. Accordingly, the reference light and the object light may interfere and an interference pattern may be formed on the screen. A general image may include only light intensity information, but the holographic image may include light intensity and phase information.

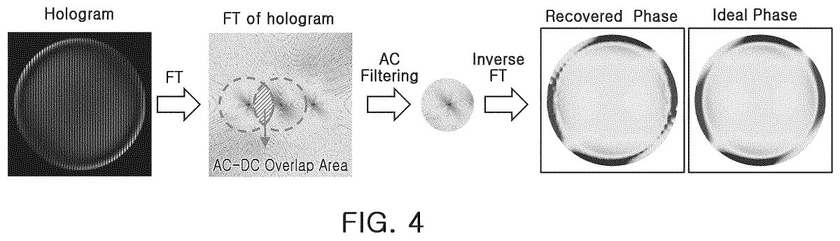

FIG. 4 is a view illustrating self-interference pupil ellipsometry using off-axis interference in a conventional semiconductor measurement device. As illustrated in FIG. 4, a hologram is generated by performing Fourier transformation on the off-axis interference pattern. By AC filtering the generated hologram and performing inverse Fourier transformation on the filtered hologram again, the phase is restored. As noted above, in the conventional art, it is difficult to achieve a desired off-axis angle. Accordingly, noise occurs during restoration due to signal overlap between AC/DC.

The semiconductor measurement device according to at least one embodiment of the present disclosure may measure/restore self-interference based on the Kramers-Kronig relation, and may thus perform restoration if AC/DC signals overlap each other. Here, the Kramers-Kronig relation states that when a copy function is analytic, the Hilbert transform below is satisfied between a real part and an imaginary part.

$${χ}_{1} ( ω ) = \frac{1}{π} 𝒫 {\int }_{- ∞}^{∞} \frac{{χ}_{2} ( {ω}^{′} )}{{ω}^{′} - ω} d {ω}^{′} \& {χ}_{2} ( ω ) = - \frac{1}{π} 𝒫 {\int }_{- ∞}^{∞} \frac{{χ}_{1} ( {ω}^{′} )}{{ω}^{′} - ω} d {ω}^{′} \\ where , χ ( ω ) = {χ}_{1} ( ω ) + i {χ}_{2} ( ω ) \qquad Equation 1$$

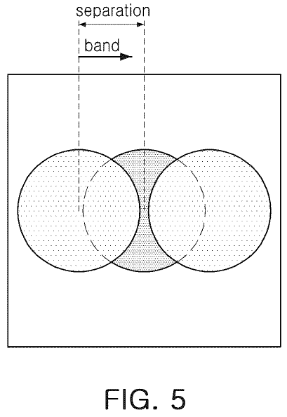

FIG. 5 is a view defining separation and a band according to at least one embodiment of the present disclosure. The separation is defined as: Separation=sin(off-axis angle): wavelength. In other words, the separation is a value obtained by dividing a sin function value of an off-axis angle by the wavelength. The band is defined as follows: Band=illumination spot radius of wafer/((focal length of Objective)÷(wavelength/M×2)). That is, the band is proportional to a radius of the illumination spot on the wafer and is inversely proportional to a focal length of the objective lens. Here, M is the pupil magnification of the optical system before passing through a beam separation unit.

Establishment conditions for self-interference measurement/analysis based on the Kramers-Kronig relation are as follows. When two electromagnetic fields interfering an off-axis are referred to as E1 and E2, “E1/E2” may be calculated with effective precision (e.g., within tolerance) if the following conditions are satisfied. At every pixel, the intensity of one of the two electromagnetic fields is always large at every pixel (E1<E2). By simply turning an angle of an analyzer after the Nomarski prism, the intensity of E1 and E2 may be adjusted. Spatial frequency separation due to the off-axis angle between E1 and E2 is greater than 0.5×band. In this case, (E1/E2)ⁿ has mostly negative frequency information, so that complex information (χ) approaches an analytic function. In the existing Fourier Transform (FT) method, information must not overlap. Accordingly, separation>2×Band is required in a spatial frequency domain of the existing Fourier Transform (FT) method. On the other hand, the KK method of the present disclosure applies a relaxed separation standard of approximately 0.5×Band. Therefore, design freedom is greatly increased because whether to overlap information is no longer decisive due to differences in restoration methods. Under conditions where the separation is less than twice the band, the restoration consistency is much better than that of the existing method.

Meanwhile, the semiconductor measurement device 10 according to at least one embodiment of the present disclosure may perform an operation of measuring the intensity of a hologram corresponding to the intensity of the electromagnetic field and the interference pattern, and an operation of restoring reflectance information from the sample using the measured intensity of the electromagnetic field and the measured intensity of the hologram and the Kramers-Kronig relation,

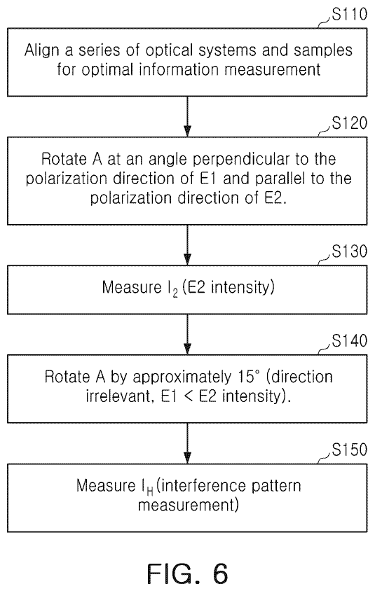

FIG. 6 is a flowchart illustrating a measurement operation of a semiconductor measurement device according to at least one embodiment of the present disclosure. Referring to FIGS. 1 to 6, the measurement operation of the semiconductor measurement device 10 may proceed as follows. A series of optical systems and sample alignment for optimal information measurement may be completed (S110). In a direction, perpendicular to a polarization direction of the first electromagnetic field E1 and parallel to a polarization direction of the second electromagnetic field E2, an angle of the analyzer (A) is rotated (S120). Accordingly, E1 may be extinguished. A polarizer (e.g., 620) behind a prism (e.g., 610) is known as the analyzer (A). Then, the detector 720 may measure I₂ (S130). I₂ is intensity information of E2. The analyzer (A) may be rotated by approximately 15° (S140). Here, a direction of rotation is irrelevant. In this case, the rotation angle is an angle that may be sufficiently counted while the intensity of E1 satisfies E1<E2. Then, the detector 720 may measure I_{H} (S150). Accordingly, the interference pattern may be measured.

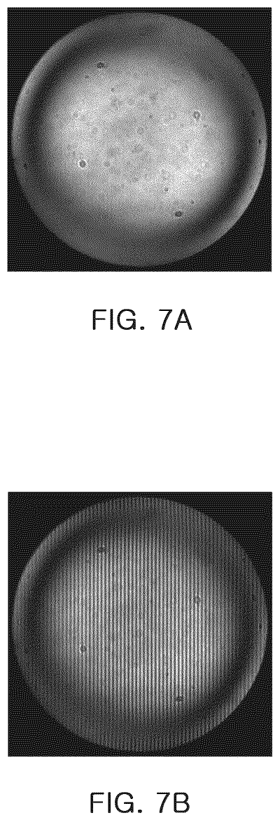

FIG. 7A is a view illustrating the measured I₂, and FIG. 7B is a view illustrating the measured I_{H}. Here, the intensity of E2 satisfies I₂=|E₂|² and the intensity of the hologram satisfies I_{H}=|E₁+E₂|².

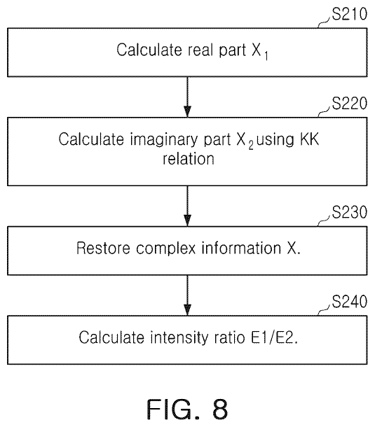

FIG. 8 is a flowchart illustrating a signal restoration operation of an off-axis analyzing device 800 according to at least one embodiment of the present disclosure. Referring to FIGS. 1 to 8, the signal restoration operation of the off-axis analyzing device 800 may proceed as follows. The off-axis analyzing device 800 may calculate an off-axis real part χ₁==½ log I_{H}/I₂ (S210). The off-axis analyzing device 800 may calculate an imaginary part χ₂ by applying the KK relation equation to χ₁ (S220). The off-axis analyzing device 800 may restore complex information χ=χ₁+iχ₂ (S230). Here, complex information (χ) satisfies the following equation.

$$\begin{matrix}χ = log ( 1 + \frac{{E}_{1}}{{E}_{2}} ) \\ = log \vert 1 + \frac{{E}_{1}}{{E}_{2}} \vert + i arg ( 1 + \frac{{E}_{1}}{{E}_{2}} ) \\ = log \vert \frac{{E}_{1} + {E}_{2}}{{E}_{2}} \vert + i arg ( 1 + \frac{{E}_{1}}{{E}_{2}} ) \\ = log \sqrt{\frac{{I}_{H}}{{I}_{2}}} + i arg ( 1 + \frac{{E}_{1}}{{E}_{2}} ) \\ = \frac{1}{2} log \frac{{I}_{H}}{{I}_{2}} + i arg ( 1 + \frac{{E}_{1}}{{E}_{2}} )\end{matrix} \qquad Equation 2$$

Complex information (χ) may be divided into a real part and an imaginary part. When χ is known, (E1/E2) may be calculated by obtaining exp(χ)−1. The off-axis analyzing device 800 may calculate an intensity ratio E1/E2 using the following equation (S240).

$$χ = log ( 1 + \frac{E 1}{E 2} ) \\ \frac{E 1}{E 2} = exp ( χ ) - 1 \qquad Equation 3$$

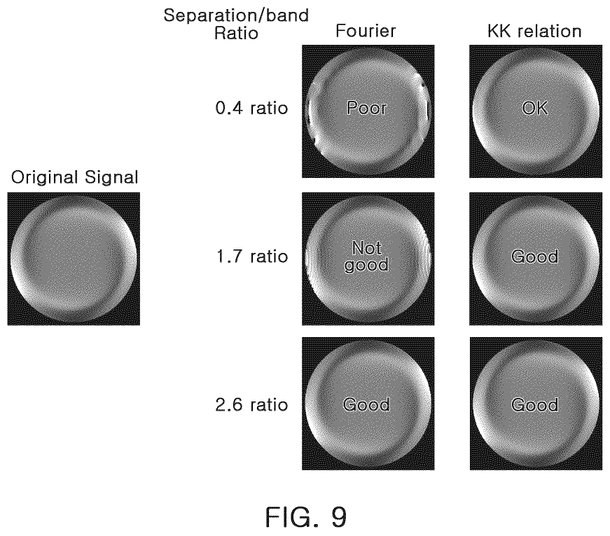

FIG. 9 is a view comparing restoration results according to a separation/band ratio according to a conventional FT restoration method and the KK restoration method of the present disclosure. Referring to FIG. 9, as compared to the conventional FT method, the KK restoration method has relaxed separation conditions and superior resilience.

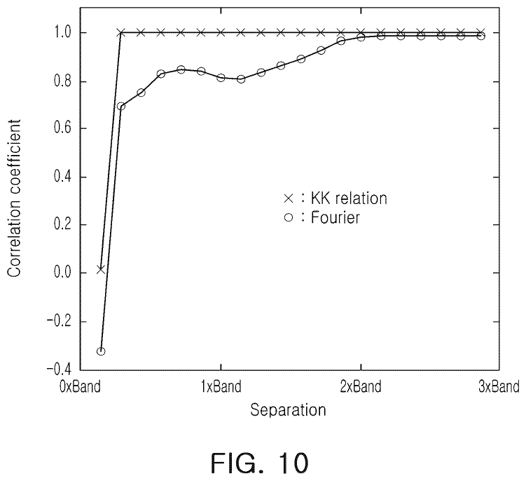

FIG. 10 is a view illustrating restoration accuracy of a semiconductor measurement device according to at least one embodiment of the present disclosure. As illustrated in FIG. 10, in the case of the conventional FT method, resilience is good starting from separation=2×band or more, but in the case of the proposed KK method, effective precision may be restored even with only a small separation (for example, conservatively, 0.5×Band or more).

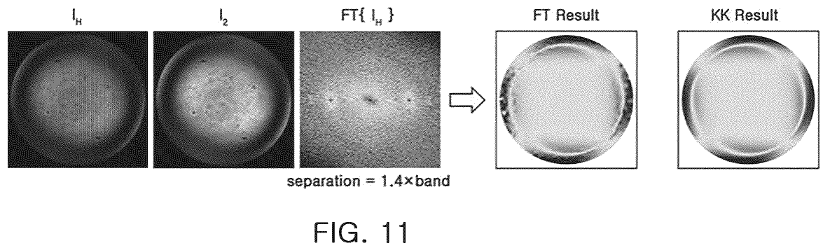

FIG. 11 is a view illustrating signal restoration results of a semiconductor measurement device according to at least one embodiment of the present disclosure. Referring to FIG. 11, FT separation=approximately 1.4×band of I_{H}, I₂, and I_{H} as actually measured is provided. Noise resulting from overlap between interfering/non-interfering signals is removed. Noise resulting from particles, which are non-interfering components, is removed.

When improving the accuracy of signal restoration using the semiconductor measurement device and an operating method thereof according to at least one embodiment of the present disclosure, measurement precision and consistency may be further improved. In the semiconductor measurement device of the present disclosure, Separation ˜1.4 Band may be satisfied so as to be irrelevant even when signal regions overlap each other (e.g., Separation=1×Band) under conditions without distortion. The semiconductor measurement device of the present disclosure may greatly improve the usability and consistency of self-interference. In the present disclosure, signal restoration based on a KK relation is used, one of the intensities of two interfering light portions is greater than the other, a relatively small angle may be used by alleviating separation conditions, a maximum band related to resolution is the same as the separation, and during the same separation as Band ˜ Separation, higher resolution may be achieved.

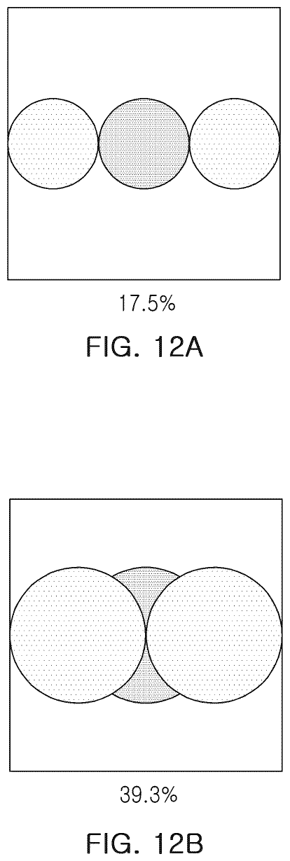

FIGS. 12A and 12B are views illustrating a maximum signal area ratio in the case of a camera reference horizontal (or vertical) off-axis structure. As illustrated in FIG. 12A, the separation according to the conventional art has a maximum signal region ratio of 17.5% based on twice the band, and as illustrated in FIG. 12B, the separation according to the present disclosure has a maximum signal region ratio of 39.3% based on the band. Here, the maximum signal region is an area of a hatched region, which is a region without information loss or overlap.

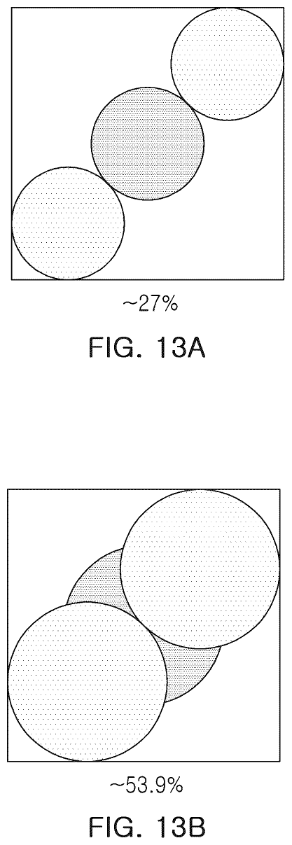

FIGS. 13A and 13B are views illustrating a maximum signal region ratio when a structure is diagonally off-axis relative to a camera. As illustrated in FIG. 13A, in the off-axis structure, the maximum signal region ratio according to the conventional method is less than 27%, and as illustrated in FIG. 13B, a maximum signal region ratio according to the method of the present disclosure is 53.9% or less.

Meanwhile, the semiconductor measurement device of the present disclosure may increase a spatial band of the hologram during measurement. Here, the spatial band is a value obtained by multiplying the resolution by the Field of View (FOV). When analyzing the spatial band of a measurement hologram, this is doubled as compared to the existing method. The amount of information that may be obtained from the same camera is doubled. This denotes that a resolution may be doubled and/or the FOV may be doubled.

In the present disclosure, a principle is provided in which when light sources, a detector, and optical components are supported in addition to ultraviolet (UV) ray, visible (VIS) ray, and infrared (IR) ray wavelength regions, example embodiments of the present disclosure are theoretically applicable to X-rays, THz waves, E-beams, and/or the like. In the present disclosure, it may be possible to improve signal precision, obtain additional information, and improve speed by simultaneously acquiring a plurality of Pupil self-interference images using multiple beam separation units.

The semiconductor measurement device of the present disclosure may be implemented with an off-axis optical system structure. A camera measurement image is a line-shaped interference pattern. Information on a Fourier plane is confirmed by applying Fourier transformation to raw data. When there is a unit that separates a beam using a birefringence prism, and the like, a self-interference structure may be employed.

In at least some embodiments, the semiconductor measurement device may be included in a device manufacturing apparatus including, e.g., a transfer chamber and at least one processing chamber. In at least one embodiment, the device manufacturing apparatus may include a transfer device (e.g., a robotic arm, a conveyer belt, etc.) configured to transfer samples between the transfer chamber, the processing chambers, and the semiconductor measurement device. The processing chamber may be configured to perform operations in the manufacturing of the semiconductor device (e.g., deposition, oxidation, etching, separating etc.) and may be controlled by processing circuitry. The processing circuitry may further apply the semiconductor measurement device to determine the status of samples produced in the at least one processing chamber and to determine a subsequent operation based on statues. The subsequent operations may include, for example, additional processing, re-processing, or discarding the sample.

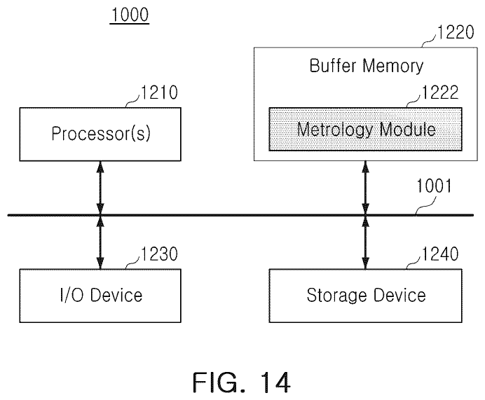

FIG. 14 is a view illustrating a computing device 1000 that processes off-axis interference analysis according to at least one embodiment of the present disclosure. The computing device 1000 may be included in and/or in communication with, e.g., the off-axis analyzing device 800 of FIG. 1. Referring to FIG. 14, the computing device 1000 may include at least one processor 1210, a memory device 1220, an input/output device 1230, and a storage device 1240 connected to a system bus 1001. Through the system bus, the processor 1210, the memory device 1220, the input/output device 1230, and the storage device 1240 may be electrically connected and may exchange data with each other. Meanwhile, the configuration of the system bus 1001 is not limited to the aforementioned description and may further include mediation means for efficient management.

At least one processor 1210 may be implemented to control an overall operation of the computing device 1000. The processor 1210 may be implemented to execute at least one instruction. For example, the processor 1210 may be implemented to execute software (application programs, operating systems, device drivers) to be executed in the computing device 1000. The processor 1210 may execute an operating system loaded into the memory device 1220. The processor 1210 may execute various application programs to be driven based on an operating system. For example, the processor 1210 may drive a metrology tool 1222 read from the memory device 1220. In at least one embodiment, the processor 1210 may be a Central Processing Unit (CPU), a microprocessor, an Application Processor (AP), or any similar processing device. In at least one embodiment, the processor 1210 may be implemented to execute a metrology tool 1222.

The memory device 1220 may be implemented to store at least one instruction. For example, the memory device 1220 may be loaded with an operating system or application programs. When the computing device 1000 boots, an OS image stored in the storage device 1240 may be loaded into the memory device 1220 based on a boot sequence. All input/output operations of the computing device 1000 may be supported by the operating system. Similarly, application programs may be loaded into the memory device 1220 so as to be selected by a user or provide basic services.

The metrology tool 1222 may be loaded into the memory device 1220 from the storage device 1240. The metrology tool 1222 may analyze/measure self-interference based on the KK relationship described in FIGS. 1 to 13. As described in FIGS. 1 to 13, the metrology tool 1222 may measure a holographic image using self-interference or restore a reflected light signal using the Kramers-Kronig relation.

Additionally, the memory device 1220 may be a volatile memory such as a Dynamic Random Access Memory (DRAM), a Static Random Access Memory (SRAM), or the like, and may be a non-volatile memory such as a flash memory, a Phase Change Random Access Memory (PRAM), a Resistance Random Access Memory (RRAM), a Nano Floating Gate Memory (NFGM), a Polymer Random Access Memory (PoRAM), a Magnetic Random Access Memory (MRAM), and Ferroelectric Random Access Memory (FRAM).

The input/output device 1230 may be implemented to control user input and output from a user interface device. For example, the input/output device 1230 may be provided with an input means such as a keyboard, a keypad, a mouse, a touch screen, and the like, to receive information from a designer. Using the input/output device 1230, the designer may receive information on a semiconductor region or data paths that require adjusted operating characteristics. Additionally, the input/output device 1230 may be provided with an output means such as a printer or a display, thus displaying a processing process and results of the metrology tool 1222.

The storage device 1240 may be provided as a storage medium of the computing device 1000. The storage device 1240 may store application programs, OS images, and measurement tools. The storage device 1240 may be provided in the form of a mass storage device such as a memory card (e.g., MMC, eMMC, SD, Micro SD, etc.), a Hard Disk Drive (HDD), a Solid State Drive (SSD), a Universal Flash Storage (UFS), and the like.

The devices described above may be implemented with (and/or controlled by) processing circuitry, such as hardware components, software components, and/or a combination of the hardware components and the software components. For example, the devices and components described in the example embodiments may be implemented using one or more general-purpose computers or special-purpose computers, such as a processor, a controller, an arithmetic logic unit (ALU), a digital signal processor, a microcomputer, a field programmable gate array (FPGA), a programmable logic unit (PLU), a microprocessor, or any other device capable of executing and responding to instructions. The processing device may execute an operating system (OS) and one or more software applications running on the operating system. Additionally, the processing device may access, store, manipulate, process, and generate data in response to the execution of software. For ease of understanding, in some cases, one processing device has been described as being used, but a person having ordinary knowledge in the art may understand that the processing device may include a plurality of processing elements or a plurality of types of processing elements. For example, the processing device may include a plurality of processors or one processor and one controller. Additionally, other processing configurations, such as parallel processors, may be possible.

Software may include computer programs, code, instructions, or a combination of one or more of these, and may configure the processing device to operate as desired or may command the processing device independently or collectively. Software or data may be embodied in any type of machine, component, physical device, virtual device, computer storage medium, or device, so as to be interpreted by the processing device or to provide instructions or data to the processing device. The software may be distributed over networked computer systems and thus stored or executed in a distributed manner. The software and data may be stored on one or more computer-readable recording media.

A pupil ellipsoidal polarization measurement device according to at least one embodiment of the present disclosure may restore reflectance information including an optical illumination system, a first detector configured to measure a signal in which the self-interference occurs on a pupil plane, and a second detector configured to detect a wafer image for alignment, in measurement of the semiconductor structure.

A semiconductor measurement device and an operating method according to an embodiment of the present invention may relax separation conditions by restoring reflectance information using self-interference patterns and Kramers-Kronig relations. The semiconductor measurement device and the operating method may restore reflectance information more clearly.

Meanwhile, the contents of the present disclosure described above are only specific examples for performing the present disclosure. The present disclosure may include not only concrete and practically usable means, but also technical ideas, which are abstract and conceptual ideas that may be used as technology in the future.

1. An operating method of a semiconductor measurement device including an optical system, comprising:
aligning the optical system and a sample to be measured;
adjusting an angle of an analyzer included in the optical system to extinguish, with an interference generator, a first electromagnetic field from a light reflected from the sample, the light including the first electromagnetic field and a second electromagnetic field;
measuring an intensity of the second electromagnetic field;
generating a hologram of the sample by rotating the analyzer to a first rotation angle; and
measuring an interference pattern by measuring an intensity of the hologram.

2. The operating method of the semiconductor measurement device of claim 1, wherein
the sample includes a wafer, and
the aligning includes aligning the wafer using an optical vision system.

3. The operating method of the semiconductor measurement device of claim 1, wherein the interference generator includes a prism configured to separate the light reflected from the sample into the first electromagnetic field and the second electromagnetic field having a different polarization to the first electromagnetic field.

4. The operating method of the semiconductor measurement device of claim 1, wherein the adjusting the angle of the analyzer comprises:
adjusting the angle of the analyzer to be perpendicular to a polarization direction of the first electromagnetic field and to be parallel to a polarization direction of the second electromagnetic field.

5. The operating method of the semiconductor measurement device of claim 1, wherein the rotating the analyzer to the first rotation angle includes rotating the analyzer such that an intensity of the first electromagnetic field is less than the intensity of the second electromagnetic field.

6. The operating method of the semiconductor measurement device of claim 5, wherein the first rotation angle is 15°.

7. The operating method of the semiconductor measurement device of claim 1, further comprising:
restoring reflectance information about the sample based on a Kramers-Kronig relation of the intensity of the second electromagnetic field and the intensity of the hologram.

8. The operating method of the semiconductor measurement device of claim 7, wherein the determining the reflectance information includes:
determining a phase difference of the first electromagnetic field and the second electromagnetic field based on a ratio between the intensity of the first electromagnetic field and the intensity of the second electromagnetic.

9. The operating method of the semiconductor measurement device of claim 8, wherein the first electromagnetic field and the second electromagnetic field interfere such that a spatial frequency has a negative frequency in the ratio.

10. The operating method of the semiconductor measurement device of claim 9, wherein, in response to the Kramers-Kronig relation being satisfied, the ratio is determined using Hilbert Transform.

11. An operating method of a semiconductor measurement device, comprising:
irradiating a light to a sample;
measuring an intensity of an electromagnetic field and an intensity of a hologram corresponding to an interference pattern from light reflected from the sample; and
restoring reflectance information about the sample based on a Kramers-Kronig relation using the measured intensity of the electromagnetic field and the measured intensity of the hologram.

12. The operating method of the semiconductor measurement device of claim 11, wherein the restoring reflectance information comprises:
determining complex information corresponding to the reflectance information.

13. The operating method of the semiconductor measurement device of claim 12, wherein the complex information includes a real part and an imaginary part, and
the determining complex information comprises:
determining the real part using the intensity of the electromagnetic field and the intensity of the hologram; and
determining the imaginary part by applying the Kramers-Kronig relation to the real part.

14. The operating method of the semiconductor measurement device of claim 12, wherein the complex information includes a real part and an imaginary part, and
the determining complex information comprises:
determining the reflectance information using the complex information.

15. The operating method of the semiconductor measurement device of claim 11, wherein the interference pattern is an off-axis interference pattern in a pupil plane.

16. An operating method of a semiconductor measurement device, comprising:
irradiating monochromatic light to a sample;
separating light reflected from the sample into at least two electromagnetic fields;
generating an off-axis interference pattern from the separated light; and
determining reflectance information of the reflected light from the off-axis interference pattern based on a Kramers-Kronig relation of the separated light.

17. The operating method of the semiconductor measurement device of claim 16, further comprising:
generating the monochromatic light.

18. The operating method of the semiconductor measurement device of claim 16, further comprising:
aligning the sample on a wafer using an optical vision system.

19. The operating method of the semiconductor measurement device of claim 16, wherein the at least two electromagnetic fields include a first electromagnetic field and a second electromagnetic field, and the generating the off-axis interference pattern comprises:
generating the off-axis interference pattern based on an interference of the first electromagnetic field and the second electromagnetic field using a polarizing prism and an analyzer.

20. The operating method of the semiconductor measurement device of claim 19, wherein the generating the off-axis interference pattern includes generating the off-axis interference pattern such that an intensity of the second electromagnetic field is greater than an intensity of the first electromagnetic field, and
due to an off-axis angle, a spatial frequency separation is greater than 0.5 times a band of the monochromatic light irradiated to the sample.

21.-25. (canceled)
